(19) United States
(12) Patent Application Publication
(10) Pub. No.: US 2026/0313955 A1
(43) Pub. Date: Oct. 8, 2026

(54) SEMICONDUCTOR DEVICE INCLUDING TERMINATION TRENCH STRUCTURE OR SEGMENT

(71) Applicant: Infineon Technologies Dresden AG & Co. KG, Dresden (DE)

(72) Inventors: Andreas Meiser, Sauerlach (DE); Ralf Rudolf, Dresden (DE); Christian Kampen, München (DE); Till Schlösser, München (DE)

(21) Appl. No.: 19/639,828

(22) Filed: Apr. 6, 2026

(30) Foreign Application Priority Data
Apr. 7, 2025 (DE) 102025113643.2

(51) Int. Cl. H10D 30/66; H10D 30/01; H10D 64/00

(52) U.S. Cl. CPC H10D 30/665; H10D 30/0297; H10D 30/668; H10D 30/669; H10D 64/117

(57) ABSTRACT

A semiconductor device is proposed. The semiconductor device includes: a source region at a first surface of a semiconductor substrate; a drain region spaced from the source region along a first lateral direction; a gate trench structure arranged, along the first lateral direction, between the source region and the drain region; a field trench structure arranged, along the first lateral direction, between the gate trench structure and the drain region; and a termination trench structure or segment spaced from the field trench structure along a second lateral direction. A depth of the termination trench structure or segment in relation to the first surface is larger than a depth of the field trench structure in relation to the first surface.

### TECHNICAL FIELD

The present disclosure relates to a semiconductor device and a method for manufacturing the same. Specifically, the present disclosure pertains to a semiconductor device featuring gate, field, and termination trench structures.

### BACKGROUND

In the field of semiconductor devices, it is common to utilize trench structures to enhance the performance and reliability of electronic components. Some devices involve the use of gate trenches, field trenches, and termination trenches to manage electric fields and improve the overall efficiency of the device. These trench structures are integral in defining the operational characteristics of the semiconductor device, such as its switching speed, breakdown voltage, and area-specific on-state resistance, RₒₙxA.

The depth and width of these trench structures are critical parameters that influence the device's performance. For instance, the gate trench is often designed to control the channel region effectively, while the field trench helps in managing the electric field distribution between the source and drain regions. The termination trench, on the other hand, is crucial for preventing edge breakdown and ensuring the device can handle high voltages without failure. Despite the substantial advances in the field of trench-based semiconductor devices, there remain challenges in optimizing these structures to achieve better performance and reliability.

One of the issues with existing semiconductor devices is the difficulty in balancing the depth and width of the trench structures to optimize electric field distribution and minimize leakage currents. Variations in the trench dimensions can lead to uneven electric fields, which may cause premature breakdown or reduced efficiency. Additionally, the process of forming these trenches with precise dimensions and maintaining consistency across the semiconductor substrate is complex and often results in manufacturing challenges.

Furthermore, the integration of multiple trench structures within a single device requires careful consideration of their relative positions and interactions. Misalignment or improper spacing between the gate, field, and termination trenches can adversely affect the device's performance.

There remains a need for improved methods and designs that address the issues of trench depth, width, and alignment to enhance device performance and reliability. It is therefore a technical problem underlying the present invention to provide a semiconductor device with optimized trench structures.

### SUMMARY

An example of the present disclosure relates to a semiconductor device including a source region at a first surface of a semiconductor substrate. The semiconductor device further includes a drain region spaced from the source region along a first lateral direction. The semiconductor device further includes a gate trench structure arranged, along the first lateral direction, between the source region and the drain region. The semiconductor device further includes a field trench structure arranged, along the first lateral direction, between the gate trench structure and the drain region. The semiconductor device further includes a termination trench structure or segment spaced from the field trench structure along a second lateral direction. A depth of the termination trench structure or segment in relation to the first surface is larger than a depth of the field trench structure in relation to the first surface.

Another example of the present disclosure relates to a method of manufacturing a semiconductor device. The method includes forming a source region at the first surface of a semiconductor substrate. The method further includes forming a drain region spaced from the source region along a first lateral direction. The method further includes forming a gate trench structure arranged, along the first lateral direction, between the source region and the drain region. The method further includes forming a field trench structure arranged, along the first lateral direction, between the gate trench structure and the drain region. The method further includes forming a termination trench structure or segment spaced from the field trench structure along a second lateral direction. A depth of the termination trench structure or segment in relation to the first surface is larger than a depth of the field trench structure in relation to the first surface.

Those skilled in the art will recognize additional features and advantages upon reading the following detailed description, and upon viewing the accompanying drawings.

### BRIEF DESCRIPTION OF THE DRAWINGS

The accompanying drawings are included to provide a further understanding of the embodiments and are incorporated in and constitute a part of this specification. The drawings illustrate examples of semiconductor devices and together with the description serve to explain principles of the examples. Further examples are described in the following detailed description and the claims.

FIG. 1A is a schematic top view for illustrating a configuration example of a FET including a termination trench structure and a field trench structure.

FIG. 1B is an exemplary cross-sectional view along line AA’ of the FET illustrated in FIG. 1A.

FIG. 2A is a schematic top view for illustrating a further configuration example of a FET including a termination trench structure and a field trench structure.

FIG. 2B is an exemplary cross-sectional view along line A-A’ of the FET illustrated in FIG. 2A.

FIG. 2C is an exemplary cross-sectional view along line B-B’ of the FET illustrated in FIG. 2A.

FIG. 3 is a schematic top view for illustrating a configuration example of a semiconductor device including a FET in a transistor cell area and a sensor element in an element area.

FIG. 4 is an exemplary process illustration of manufacturing a semiconductor device.

### DETAILED DESCRIPTION

In the following detailed description, reference is made to the accompanying drawings, which form a part hereof and in which are shown by way of illustrations specific examples of FETs. It is to be understood that other examples may be utilized and structural or logical changes may be made without departing from the scope of the present disclosure. For example, features illustrated or described for one example can be used in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms "having", "containing", "including", "comprising" and the like are open, and the terms indicate the presence of stated structures, elements or features but do not preclude the presence of additional elements or features. The articles "a", "an" and "the" are intended to include the plural as well as the singular, unless the context clearly indicates otherwise.

The term "electrically connected" may describe a permanent low-resistive connection between electrically connected elements, for example a direct contact between the concerned elements or a low-resistive connection via a metal and/or heavily doped semiconductor material. The term "electrically coupled" may include that one or more intervening element(s) adapted for signal and/or power transmission may be connected between the electrically coupled elements, for example, elements that are controllable to temporarily provide a low-resistive connection in a first state and a high-resistive electric decoupling in a second state. An ohmic contact is a non-rectifying electrical junction.

Ranges given for physical dimensions may include the boundary values. For example, a range for a parameter y from a to b reads as a ≤ y ≤ b. The same holds for ranges with one boundary value like “at most” and “at least”.

The terms "on" and “over” are not to be construed as meaning only "directly on" and “directly over”. Rather, if one element is positioned "on" or “over” another element (e.g., a layer is "on" or “over” another layer or "on" or “over” a substrate), a further component (e.g., a further layer) may be positioned between the two elements (e.g., a further layer may be positioned between a layer and a substrate if the layer is "on" or “over” said substrate).

An example of the present disclosure relates to semiconductor device including a source region at a first surface of a semiconductor substrate. The semiconductor device further includes a drain region spaced from the source region along a first lateral direction. The semiconductor device further includes a gate trench structure arranged, along the first lateral direction, between the source region and the drain region. The semiconductor device further includes a field trench structure arranged, along the first lateral direction, between the gate trench structure and the drain region. The semiconductor device further includes a termination trench structure or segment spaced from the field trench structure along a second lateral direction. A depth of the termination trench structure or segment in relation to the first surface may be larger than a depth of the field trench structure in relation to the first surface.

The source region and the drain region or part thereof may be of an n-type. In this case, the FET may be an n-channel FET, for example. In some further examples, the source region and the drain region may be of a p-type. In this case, the FET may be an p-channel FET, for example. The source region and drain region are areas within the semiconductor substrate where charge carriers enter and exit, respectively.

For example, the FET may be a lateral FET. In a lateral FET, a load current flow direction is a lateral direction, e.g. the first lateral direction, and the source region and the drain region are spaced from each other along the first lateral direction. For example, the lateral FET may be a lateral trench FET such as a lateral trench metal oxide semiconductor field effect transistor, lateral trench MOSFET. In the gate trench structure, a gate trench dielectric may line sidewalls and a bottom side of a trench and may electrically isolate a gate trench electrode from a surrounding part of the semiconductor substrate. In the lateral trench FET, a channel current may flow along the first lateral direction at opposite sidewalls and along a bottom side of the gate trench structure, for example.

For example, the FET may be implemented monolithically using a mixed technology. Such mixed technologies can be used, for example, to form analog circuit blocks in a chip by the bipolar devices included in this technology for providing interfaces to digital systems, and to form digital circuit blocks by the complementary metal-oxide-semiconductor (CMOS) devices included in this technology for providing signal processing, and to form low-, medium- or high-voltage or power blocks by field effect transistors included in this technology. Such mixed technologies are known, for example, as bipolar CMOS-DMOS, BCD technologies or smart power technologies, SPT, and are used in a variety of application areas in the field of e.g. lighting, motor control, automotive electronics, power management for mobile devices, audio amplifiers, power supply, hard disks, printers. The semiconductor device or FET may be part of a BCD or Smart Power chip in one of the above application fields, for example.

The semiconductor substrate may be based on various semiconductor materials, for example silicon (Si), silicon-on-insulator (SOI), silicon-sapphire (SOS), silicon-germanium, germanium, gallium arsenide, silicon carbide, gallium nitride, or other compound semiconductor materials. The semiconductor substrate may be based on a semiconductor base substrate, for example a semiconductor wafer and may include one or more epitaxial layers deposited thereon and/or may be back-thinned.

For realizing a desired current carrying capacity, the semiconductor device or FET may be designed by a plurality of transistor cells that are parallel-connected. The parallel-connected transistor cells may, for example, be transistor cells formed in the shape of a strip or a strip segment. The transistor cells may be arranged in a transistor cell area of the semiconductor substrate. The transistor cell area may be an active area where the source region of the FET and the drain region of the FET are arranged opposite to one another along the first lateral direction. In the active area, a load current may enter or exit the semiconductor substrate of the FET, e.g. via contact plugs on the first surface and/or second surface of the semiconductor substrate.

The first surface may be a front surface or a top surface of the semiconductor substrate, and a second surface may be a back surface or a rear surface of the semiconductor substrate, for example. The semiconductor substrate may be attached to a lead frame via the second surface, for example. Over the first surface and/or second surface of the semiconductor substrate, bond pads may be arranged and bond wires may be bonded on the bond pads, for example.

The source region and the body region may be electrically connected to a source electrode via a source region contact and a body region contact, respectively. The source electrode may be part of a wiring area over the first surface of the semiconductor substrate, for example. The wiring area may include one or more than one, e.g. two, three, four or even more wiring levels. Each wiring level may be formed by a single one or a stack of conductive layers, e.g. metal layer(s). The wiring levels may be lithographically patterned, for example. Between stacked wiring levels, an interlayer dielectric structure may be arranged. Contact plug(s) or contact line(s) may be formed in openings in the interlayer dielectric structure to electrically connect parts, e.g. metal lines or contact areas, of different wiring levels to one another. The source electrode may be formed by one or more elements of the wiring area. Likewise, the semiconductor device or FET may further include a drain electrode. Also the drain electrode may be formed by one or more elements of the wiring area over the first surface. For example, the source electrode and the drain electrode may include separate parts of a patterned first wiring level, e.g. a first metal layer. In some examples, the drain electrode may be formed over the second surface of the semiconductor substrate. In this case, a drain region of the FET may be electrically connected to the drain electrode by a through contact or trench contact extending at least partly through the semiconductor substrate.

A gate trench dielectric of the gate trench structure electrically isolates a gate trench electrode from a surrounding part of the semiconductor substrate, for example. For example, the gate trench dielectric may be an insulating material such as an oxide, e.g., SiO₂, a nitride, e.g., Si₃N₄, a high-k dielectric, or a low-k dielectric, or any combination thereof. For example, the gate trench dielectric may be formed as a thermal oxide. The gate trench electrode may be formed of one or more conductive materials, e.g. metal, metal silicide, metal compound, highly doped semiconductor material such as highly doped polycrystalline silicon. For example, the gate trench electrode may be a single layer, e.g. a highly doped polycrystalline layer, or a stack of layers.

For example, the source region may adjoin a first sidewall of the gate trench structure. A drift region may be arranged, along the first lateral direction, between the gate trench structure and the drain region. The drift region may adjoin a second sidewall of the gate trench structure. The second sidewall may be opposite to the first sidewall along the first lateral direction.

For example, the gate trench structure is designed to control the channel region effectively, while the field trench structure may help in improving the tradeoff between voltage blocking capability and area-specific on-state resistance, RₒₙxA, by managing the electric field distribution between the source and drain regions. The termination trench structure, on the other hand, is crucial for preventing edge breakdown and ensuring the device can handle high voltages without failure. The termination trench structure or segment may partly or fully surround the transistor cell area, for example.

The advantages of the examples described herein include improved control over the electric field distribution within the device, which can enhance performance and reliability. The deeper termination trench structure or segment provides better isolation and helps to manage high voltage conditions more effectively. This design can lead to more efficient and robust semiconductor devices suitable for various applications.

For example, the depth of the termination trench structure or segment may be by 1 to 10 µm, or by 1 to 5 µm larger than the depth of the field trench structure or segment.

The implementation introduces a specific quantitative relationship between the depth of the termination trench structure or segment and the depth of the field trench structure or segment. This design brings a precise dimensional specification to the semiconductor device, which can influence the electrical characteristics and performance of the device, e.g. by affecting factors such as electric field distribution, breakdown voltage, and overall device reliability by influencing the avalanche breakdown behavior of the semiconductor device.

For example, a width of the termination trench structure or segment may be larger than a width of the field trench structure.

The increased width of the termination trench may result in the desired larger depth compared with the depth of the field trench structure or segment, e.g. when concurrently processing the gate, field and termination trenches by a masked anisotropic etch process such as, for example, reactive ion etching (RIE).

For example, the gate trench structure includes a gate trench electrode and a gate trench dielectric arranged between the gate trench electrode and the semiconductor substrate. Similarly, the field trench structure includes a field trench electrode and a field trench dielectric arranged between the field trench electrode and the semiconductor substrate. The termination trench structure or segment includes a termination trench electrode and a termination trench dielectric arranged between the termination trench electrode and the semiconductor substrate. The thickness of the field trench dielectric may be larger than the thickness of the gate trench dielectric, and the thickness of the termination trench dielectric may be larger than the thickness of the gate trench dielectric. This differentiation in dielectric thicknesses among the trench structures enhances the device's performance by potentially improving the electric field distribution and breakdown voltage characteristics, thereby contributing to the overall efficiency and reliability of the semiconductor device.

For example, the thickness of the field trench dielectric may be equal to the thickness of the termination trench dielectric. This feature may simplify the manufacturing process by allowing for a common dielectric deposition step for both trench structures, thus reducing complexity and manufacturing costs.

For example, the gate trench electrode, the field trench electrode, and the termination trench electrode may be separate parts of a patterned layer. The patterned layer may be a patterned layer formed of a conductive material or stack of materials, e.g. metal, doped semiconductor material such as doped polycrystalline silicon or doped SiGe.

The fabrication of the electrodes as separate parts within a patterned layer also suggests potential benefits in terms of manufacturing scalability and cost-effectiveness, as it may allow for more straightforward fabrication processes.

For example, the semiconductor device may further include a body region adjoining the termination trench structure or segment along the second lateral direction or being spaced from the termination trench structure or segment by less than 2 µm, or even less than 1 µm, along the second lateral direction.

The proximity of the body region to the termination trench structure or segment ensures that the electric field distribution is optimized, which can lead to improved breakdown voltage characteristics.

For example, the field trench structure is one of a plurality of field trench structures arranged with a first pitch along the second lateral direction. The body region is spaced from the termination trench structure or segment by at most half of the first pitch along the second lateral direction.

The introduction of a plurality of field trench structures suggests a repeated pattern or array, which may be beneficial for enhancing the device's performance, such as improving current carrying capacity. The arrangement with a specific pitch indicates a regular spacing between these structures, which can be crucial for achieving uniform electrical characteristics across the semiconductor device. By limiting the spacing to at most half of the first pitch, the design aims to improve termination capability and compact device layout.

For example, the semiconductor substrate includes a semiconductor base substrate. The semiconductor substrate further includes a first semiconductor layer on the semiconductor base substrate, and a second semiconductor layer on the first semiconductor layer. A doping concentration of the second semiconductor layer may be by a factor of at least 2 larger than a doping concentration of the first semiconductor layer.

The variation in doping concentration between the layers can influence the electric field distribution, and overall device performance. By having a lower doping concentration in the first semiconductor layer compared to the second, the device can achieve a gradient in electrical characteristics, which can be beneficial for improving the tradeoff between voltage blocking capability and area-specific on-state resistance, RₒₙxA.

For example, a bottom side of the body region may be arranged in the first semiconductor layer.

The body region typically acts as a channel for current flow between the source and drain regions and forms a pn junction with the drift region in the semiconductor substrate. By situating the bottom side of the body region in the first semiconductor layer, the implementation may allow for improving the device's breakdown behavior.

For example, a bottom side of the first semiconductor layer may have a larger vertical distance from the first surface than the bottom side of the field trench electrode.

This structural differentiation can influence the electrical characteristics and performance of the device, potentially enhancing its ability to improving the tradeoff between voltage blocking capability and area-specific on-state resistance, RₒₙxA by the impact of the field trench structure.

For example, the termination trench structure or segment may include a plurality of contiguous segments bordering an element area of the semiconductor substrate at the first surface. The element area is separated from the trench gate structure along the second lateral direction by the termination trench structure or segment.

The element area is separated from the transistor cell area and may include a sensor element in the element area. By bordering the element area there is a clear separation between the sensor element and the transistor cell area, which can improve the efficiency of the device by minimizing leakage currents and other parasitic effects. For example, parasitic bipolar transistor triggering, e.g. parasitic pnp triggering between a p-doped region in the transistor cell area (e.g. p-doped body regions) and a p-doped region in the element area (e.g. p-doped sensor element regions) via an n-doped semiconductor substrate as base of the parasitic pnp may be reduced or suppressed.

For example, a bottom side of the termination trench structure or segment may be arranged in the semiconductor base substrate, the semiconductor base substrate having a larger doping concentration than the second semiconductor layer. This may allow for further improving reduction or suppression of parasitic bipolar transistor triggering between the transistor cell area and the element area via the semiconductor base substrate

Details with respect to structure, or function, or technical benefit of features described above with respect to a semiconductor device such as a FET likewise apply to the exemplary methods described further below. Processing the semiconductor substrate body may comprise one or more optional additional features corresponding to one or more aspects mentioned in connection with the proposed concept or one or more examples described above or below.

It is to be understood that the disclosure of multiple acts, processes, operations, steps or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub–acts, -functions, -processes, -operations or –steps, respectively. Such sub acts may be included and part of the disclosure of this single act unless explicitly excluded.

An example of a method of manufacturing a semiconductor device includes forming a source region at the first surface of a semiconductor substrate. The method further includes forming a drain region spaced from the source region along a first lateral direction. The method further includes forming a gate trench structure arranged, along the first lateral direction, between the source region and the drain region. The method further includes forming a field trench structure arranged, along the first lateral direction, between the gate trench structure and the drain region. The method further includes forming a termination trench structure or segment spaced from the field trench structure along a second lateral direction. A depth of the termination trench structure or segment in relation to the first surface is larger than a depth of the field trench structure in relation to the first surface.

For example, trenches of the gate trench structure, the field trench structure, and the termination trench structure or segment may be concurrently formed by a masked etch process.

The concurrent formation of the trenches also facilitates better alignment and positioning of the gate trench structure, field trench structure, and termination trench structure or segment relative to each other, ensuring that their spatial relationships are maintained as intended. The concurrent formation of the trenches further enhances manufacturing efficiency by reducing the number of separate etching steps required, thereby potentially lowering production time and costs.

For example, the method may further include forming a body region in the semiconductor substrate before forming the trenches of the gate trench structure, the field trench structure, and the termination trench structure or segment.

For example, a gate trench electrode of the gate trench structure, a field trench electrode of the field trench structure, and a termination trench electrode of the termination trench structure or segment may be concurrently formed by a layer deposition process.

The layer deposition process may be a physical and/or chemical layer deposition process for forming a conductive material or stack of materials, e.g. metal, doped semiconductor material such as doped polycrystalline silicon or doped SiGe.

For example, forming the semiconductor substrate may include forming a first semiconductor layer on a semiconductor base substrate, and forming a second semiconductor layer on the first semiconductor layer. A doping concentration of the second semiconductor layer may be set larger by a factor of at least 2 than a doping concentration of the first semiconductor layer.

For example, forming the body region may include positioning a bottom side of the body region in the first semiconductor layer.

Details with respect to structure, or function, or technical benefit of features described above with respect to a semiconductor device such as a FET likewise apply to the illustrated FETs described further below with respect to the figures.

The description and drawings merely illustrate the principles of the disclosure. Furthermore, all examples recited herein are principally intended expressly to be only for illustrative purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

In the following, further examples of semiconductor devices exemplified as field effect transistors, FETs, are explained in connection with the accompanying drawings. Functional and structural details described with respect to the examples above shall likewise apply to the exemplary embodiments illustrated in the figures and described further below.

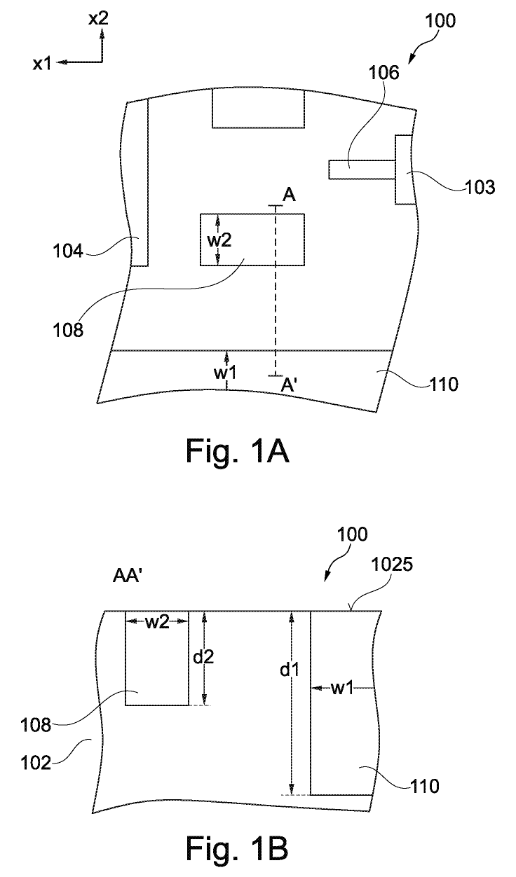

FIG. 1A schematically and exemplarily shows a top view of a configuration example of a FET 100.

FIG. 1B schematically and exemplarily shows a cross-sectional view along line AA’ of FIG. 1A.

The schematic top view of FIG. 1A illustrates the spatial arrangement of various regions and structures within the FET 100. The semiconductor substrate 102 is depicted with a first surface 1025. The source region 103 is positioned at the first surface 1025 and is spaced from the drain region 104 along a first lateral direction x1. Between the source region 103 and the drain region 104, a gate trench structure 106 is arranged along the first lateral direction x1. Further along the first lateral direction x1, a field trench structure 108 is positioned between the gate trench structure 106 and the drain region 104. Additionally, a termination trench structure or segment 110 is shown, spaced from the field trench structure 108 along a second lateral direction x2. The first lateral direction x1 is illustrated as a longitudinal direction of each of the gate trench structure 106 and the field trench structure 108.

The schematic cross-sectional view of FIG. 1B along the line AA' of the FET 100 illustrated in FIG. 1A provides exemplary details regarding the depths and widths of the trench structures. The cross-section reveals that the termination trench structure or segment 110 has a depth d1, which is greater than the depth d2 of the field trench structure 108. The width w1 of the termination trench structure or segment 110 is also shown to be larger than the width w2 of the field trench structure 108. The semiconductor substrate 102 is depicted with the first surface 1025, where the various trench structures are formed.

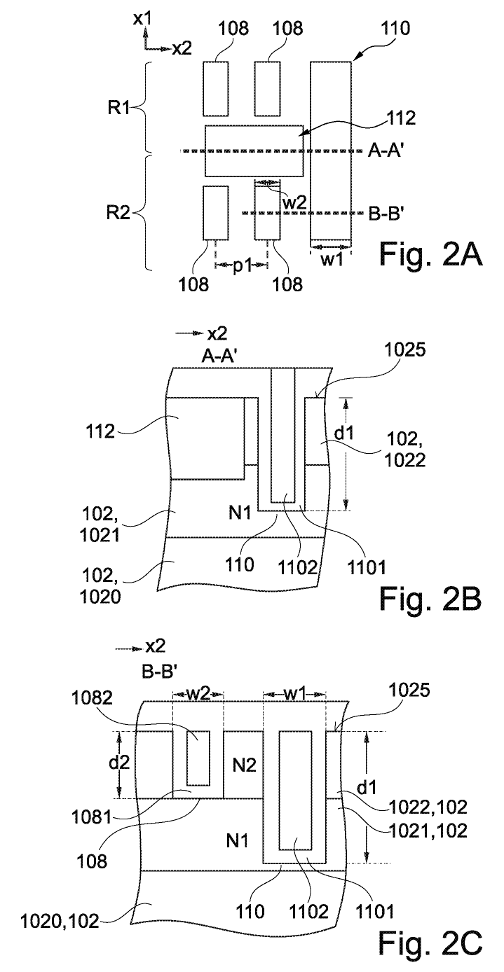

The schematic top view of FIG. 2A illustrates further exemplary features of a configuration example of a FET 100.

In top view of FIG. 2A, only selected regions and structures within the FET 100 are illustrated for describing the spatial arrangement and dimensions of these regions while other regions, e.g. source, gate structure, or drain, are omitted in the simplified illustration.

In the FET 100, the termination trench or segment 110 terminates two rows R1, R2 of FET cells. The field trench structures 108 are arranged with a first pitch p1 along the second lateral direction x2. A body region 112 is spaced from the termination trench or segment 110 along the second lateral direction x2, e.g. by less than 2 µm, or by less than 1µm. In one example, the body region 112 is spaced from the termination trench structure or segment 110 along the second lateral direction x2 by at most half of the first pitch p1. According to a further example not illustrated in FIG. 2A, the body region 112 may also adjoin the termination trench or segment 110 along the second lateral direction x2. The body region 112 is further spaced from the field trench structures 108 along the first lateral direction x1. The width w1 of the termination trench structure or segment 110 is also shown to be larger than the width w2 of the field trench structure 108.

A schematic cross-sectional view along line A-A' of the FET 100 illustrated in FIG. 2A is shown in FIG. 2B, and a schematic cross-sectional view along line B-B' of the FET 100 illustrated in FIG. 2A is shown in FIG. 2C.

The depth d1 of the termination trench structure or segment 110 is larger than the depth d2 of the field trench structure, e.g. by 1 to 10 µm or by 2 to 5 µm.

A field trench electrode 1082 of the field trench structure 108 is separated from a surrounding part of the semiconductor substrate 102 by a field trench dielectric 1081, and a termination trench electrode 1102 of the termination trench structure or segment 110 is separated from a surrounding part of the semiconductor substrate 102 by a termination trench dielectric 1101. The field trench dielectric 1081 may line sidewalls and a bottom side of a trench of the field trench structure 108. The termination trench dielectric 1101 may line sidewalls and a bottom side of a trench of the termination trench structure or segment 110. A thickness of the field trench dielectric 1081 may be equal to the thickness termination trench dielectric 1101 when concurrently forming the dielectrics, for example.

The semiconductor substrate 102 includes a semiconductor base substrate 1020, a first semiconductor layer 1021 on the semiconductor base substrate 1020, and a second semiconductor layer 1022 on the first semiconductor layer 1021. For example, a doping concentration N2 of the second semiconductor layer 1022 may be by a factor of at least 2 larger than a doping concentration N1 of the first semiconductor layer 1021.

As is schematically illustrated in the cross-sectional view of FIG. 2B, a bottom side of the body region 112 extends into the first semiconductor layer 1021.

As is schematically illustrated in the cross-sectional view of FIG. 2C, a bottom side of the first semiconductor layer 1021 has a larger vertical distance from the first surface than the bottom side of the field trench electrode 1082.

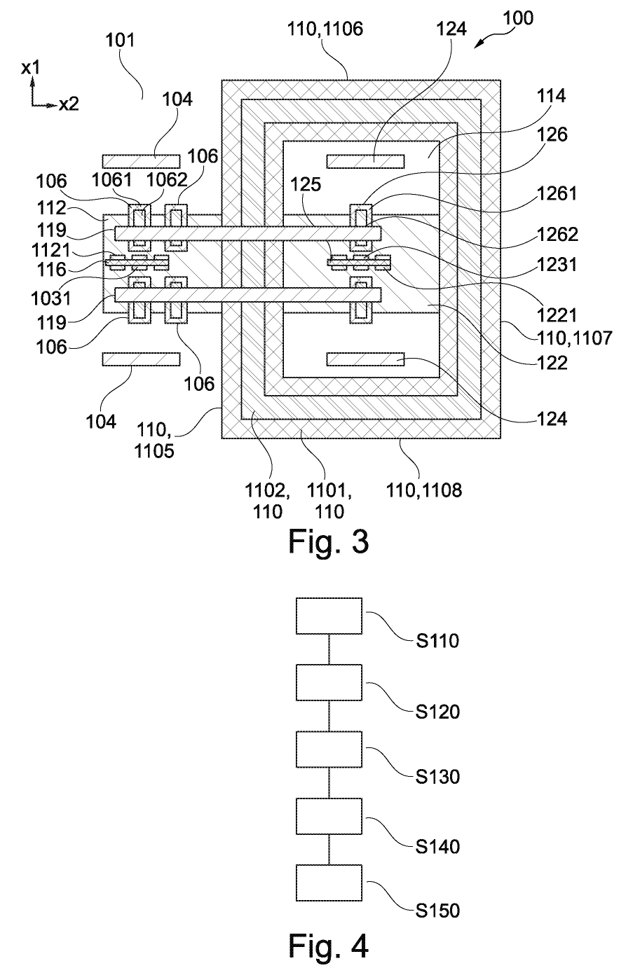

The schematic top view of FIG. 3 illustrates further exemplary features of a configuration of a FET 100. In top view of FIG. 3, only selected regions and structures within the FET 100 are illustrated for describing the spatial arrangement and dimensions of these regions while other regions, e.g. source region, are omitted in the simplified illustration.

The termination trench structure or segment 110 includes a plurality of contiguous segments 1105, 1106, 1107, 1108 bordering an element area 114 of the semiconductor substrate 102 at the first surface 1025. The termination trench structure or segment 110 includes a termination trench electrode 1102 and a termination trench dielectric 1101 arranged between the termination trench electrode 1102 and the semiconductor substrate 102. The element area 114 is separated from the gate trench structure 106 in a transistor cell area 101 along the second lateral direction x2 by the termination trench structure or segment 110.

In the element area 114, a sensor element is illustrated. For example, the sensor element may be a current sensor element having a similar layout as a transistor cell in the transistor cell area. The sensor element includes a drain region 124 in the element area 114 similar to the drain region 104 in the transistor cell area. The sensor element further includes a gate trench structure 126 having a gate trench dielectric 1261 and a gate trench electrode 1262 similar to the gate structure 106 including a gate trench dielectric 1061 and a gate trench electrode 1062 in the transistor cell area 101. A thickness of the termination trench dielectric 1101 is larger than the thickness of the gate trench dielectric 1061. A gate interconnection line 119 electrically connects the gate trench electrodes 1062, 1262 in the transistor cell area 101 and in the element area 114 together. The sensor element further includes a body region 122 similar to the body region 112 in the transistor cell area 101. The sensor element further includes a source region contact 1231 and a body region contact 1221 connected to a sensor electrode 125 in the element area 114. Likewise, a source region contact 1031 and a body region contact 1121 are connected to a source electrode 116 in the transistor cell area 101. The source electrode 116 and the sensor electrode 125 are electrically isolated. Thus, a sensor current may be extracted via the sensor electrode 125 and may be further processed by further circuitry. For example, when the sensor current exceeds a threshold current, this may trigger turning off the transistor cells in the transistor cell array.

It is to be understood that the disclosure of multiple acts, processes, operations, steps or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub–acts, -functions, -processes, -operations or –steps, respectively. Such sub acts may be included and part of the disclosure of this single act unless explicitly excluded.

An example of a method of manufacturing a semiconductor device is illustrated by referring to the flowchart of FIG. 4.

Process feature S110 includes forming a source region at the first surface of a semiconductor substrate.

Process feature S120 includes forming a drain region spaced from the source region along a first lateral direction.

Process feature S130 includes forming a gate trench structure arranged, along the first lateral direction, between the source region and the drain region.

Process feature S140 includes forming a field trench structure arranged, along the first lateral direction, between the gate trench structure and the drain region.

Process feature S150 includes forming a termination trench structure or segment spaced from the field trench structure along a second lateral direction, and wherein a depth of the termination trench structure or segment in relation to the first surface is larger than a depth of the field trench structure in relation to the first surface.

The aspects and features mentioned and described together with one or more of the previously described examples and figures, may as well be combined with one or more of the other examples in order to replace a like feature of the other example or in order to additionally introduce the feature to the other example.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a source region at a first surface of a semiconductor substrate;
a drain region spaced from the source region along a first lateral direction;
a gate trench structure arranged, along the first lateral direction, between the source region and the drain region;
a field trench structure arranged, along the first lateral direction, between the gate trench structure and the drain region; and
a termination trench structure or segment spaced from the field trench structure along a second lateral direction,
wherein a depth of the termination trench structure or segment in relation to the first surface is larger than a depth of the field trench structure in relation to the first surface.

2. The semiconductor device of claim 1, wherein the depth of the termination trench structure or segment is by 1 to 10 µm larger than the depth of the field trench structure.

3. The semiconductor device of claim 1, wherein a width of the termination trench structure or segment is larger than a width of the field trench structure.

4. The semiconductor device of claim 1, wherein the gate trench structure includes a gate trench electrode and a gate trench dielectric arranged between the gate trench electrode and the semiconductor substrate, wherein the field trench structure includes a field trench electrode and a field trench dielectric arranged between the field trench electrode and the semiconductor substrate, wherein the termination trench structure or segment includes a termination trench electrode and a termination trench dielectric arranged between the termination trench electrode and the semiconductor substrate, wherein a thickness of the field trench dielectric is larger than a thickness of the gate trench dielectric, and wherein a thickness of the termination trench dielectric is larger than the thickness of the gate trench dielectric.

5. The semiconductor device of claim 4, wherein the thickness of the field trench dielectric is equal to the thickness of the termination trench dielectric.

6. The semiconductor device of claim 4, wherein the gate trench electrode, the field trench electrode, and the termination trench electrode are separate parts of a patterned layer.

7. The semiconductor device of claim 1, further comprising:
a body region adjoining the termination trench structure or segment along the second lateral direction or being spaced from the termination trench structure or segment by less than 2 µm along the second lateral direction.

8. The semiconductor device of claim 7, wherein the field trench structure is one of a plurality of field trench structures arranged with a first pitch along the second lateral direction, and wherein the body region is spaced from the termination trench structure or segment along the second lateral direction by at most half of the first pitch.

9. The semiconductor device of claim 1, wherein the semiconductor substrate includes a semiconductor base substrate, a first semiconductor layer on the semiconductor base substrate, and a second semiconductor layer on the first semiconductor layer, and wherein a doping concentration of the second semiconductor layer is by a factor of at least 2 larger than a doping concentration of the first semiconductor layer.

10. The semiconductor device of claim 9, wherein a bottom side of the body region is arranged in the first semiconductor layer.

11. The semiconductor device of claim 9, wherein a bottom side of the first semiconductor layer has a larger vertical distance from the first surface than the bottom side of the field trench electrode.

12. The semiconductor device of claim 9, wherein the termination trench structure or segment includes a plurality of contiguous segments bordering an element area of the semiconductor substrate at the first surface, and wherein the element area is separated from the trench gate structure along the second lateral direction by the termination trench structure or segment.

13. The semiconductor device of claim 12, further comprising:
a sensor element in the element area.

14. The semiconductor device of claim 9, wherein a bottom side of the termination trench structure or segment is arranged in the semiconductor base substrate, and wherein the semiconductor base substrate has a larger doping concentration than the second semiconductor layer.

15. A method of manufacturing a semiconductor device, the method comprising:
forming a source region at the first surface of a semiconductor substrate;
forming a drain region spaced from the source region along a first lateral direction;
forming a gate trench structure arranged, along the first lateral direction, between the source region and the drain region;
forming a field trench structure arranged, along the first lateral direction, between the gate trench structure and the drain region; and
forming a termination trench structure or segment spaced from the field trench structure along a second lateral direction,
wherein a depth of the termination trench structure or segment in relation to the first surface is larger than a depth of the field trench structure in relation to the first surface.

16. The method of claim 15, wherein trenches of the gate trench structure, the field trench structure, and the termination trench structure or segment are concurrently formed by a masked etch process.

17. The method of claim 15, further comprising:
before forming trenches of the gate trench structure, the field trench structure and the termination trench structure or segment, forming a body region in the semiconductor substrate.

18. The method of claim 15, wherein a gate trench electrode of the gate trench structure, a field trench electrode of the field trench structure, and a termination trench electrode of the termination trench structure or segment are concurrently formed by a layer deposition process.

19. The method of claim 15, wherein forming the semiconductor substrate comprises:
forming a first semiconductor layer on a semiconductor base substrate; and
forming a second semiconductor layer on the first semiconductor layer,
wherein a doping concentration of the second semiconductor layer is larger by a factor of at least 2 than a doping concentration of the first semiconductor layer.

20. The method of claim 19, further comprising:
positioning a bottom side of a body region in the first semiconductor layer.
